(19) United States
(12) Patent Application Publication
(10) Pub. No.: US 2013/0043865 A1
(43) Pub. Date: Feb. 21, 2013

(54) PAIR COMPRISING PRINTED CIRCUIT BOARD AND FURTHER BOARD AND METHOD FOR MEASURING CURRENT INTENSITY

(71) Applicants: Jens MAKUTH, Feucht (DE); Dirk SCHEIBNER, Nuremburg (DE); Jürgen SCHIMMER, Nuremburg (DE)

(72) Inventors: Jens MAKUTH, Feucht (DE); Dirk SCHEIBNER, Nuremburg (DE); Jürgen SCHIMMER, Nuremburg (DE)

(73) Assignee: SIEMENS AKTIENGESELLSCHAFT, Munich (DE)

(21) Appl. No.: 13/585,284

(22) Filed: Aug. 14, 2012

(30) Foreign Application Priority Data
Aug. 15, 2011 (DE) 102011080954.6

(51) Int. Cl. G01R 19/00; G01R 33/07; H05K 3/36; G01R 33/09

(52) U.S. Cl. 324/251; 324/126; 324/252; 29/830

(57) ABSTRACT

A current measurement is implemented with the aid of magnetoresistive sensors or Hall sensors. The sensors are arranged on one or two printed circuit boards, which provide a passage when coupled to one another, through which passage an electrical line passes. The printed circuit boards can also be fitted retrospectively to electrical lines, with the result that the electrical lines need not be interrupted.

### CROSS-REFERENCE TO RELATED APPLICATIONS

The present application hereby claims priority under 35 U.S.C. §119 to German patent application number DE 10 2011 080 954.6 filed Aug. 15, 2011, the entire contents of which are hereby incorporated herein by reference.

### BACKGROUND

1. Field

At least one embodiment relates to a method for measuring a current intensity of a current flowing through an electrical line. At least one embodiment also relates to a method for retrofitting a switchgear cabinet, which has a plurality of electrical lines. In this context, at least one embodiment relates to a pair comprising a printed circuit board and a further board, and to a printed circuit board as such.

2. Description of Related Art

Attempts are constantly being made to reduce current consumption, whether this be in the domestic or industrial sector. In order to monitor and optimize energy consumption, it is essential to have knowledge of the present consumption, if possible with respect to individual loads and load groups.

Until now, in each case, one current converter detects the current intensities, standardizes said current intensities via signal converters and finally digitizes them. The current converter is built into switchgear cabinets for a plurality of electrical lines. If it is also desired to detect other variables, further hardware components are required. This is the case, for example, when wishing to detect the phase angle in the three-phase current in order to determine reactive power losses. The installation of the measuring device is associated with a high degree of planning, design complexity and installation complexity.

It may be desirable if the current intensity of a current flowing through an electrical line, in particular in a switchgear cabinet, could be retrospectively measured more easily.

### SUMMARY

At least one embodiment facilitates retrospective provision of measuring a current intensity, and in particular, retrofitting of a switchgear cabinet.

At least one embodiment provides a pair comprising a printed circuit board and a further board.

At least one other embodiment provides a printed circuit board.

At least one other embodiment provides a method in which the pair of boards is used.

At least one other embodiment provides a method for retrofitting a switchgear cabinet with a plurality of electrical lines, in which, in turn, a method for measuring the current intensity of a current flowing through an electrical line is used.

An embodiment of the pair comprises a printed circuit board and a further board, which can be coupled to the printed circuit board, for example, by providing specific coupling devices on one or both boards, or with the aid of an auxiliary device such as a clip or the like, for example, in such a way that at least one (e.g., circular) passage for an electrical line is provided by the two boards coupled to one another owing to the coupling.

An embodiment of the printed circuit board comprises at least one sensor device for contactless measurement of a current intensity of a current flowing through an electrical line in a passage.

The actual measuring device, in the form of the sensor device, is provided by the printed circuit board. In this case, the sensor device need not touch the electrical line because it is actually designed for contactless measurement of the current intensity. The printed circuit board can be fastened in a relatively simple manner to the electrical line or a fastening means for the electrical line by virtue of it being coupled to the further board, then the two boards surround the electrical line, to be relatively precise without the electrical line needing to be interrupted, dismantled or the like.

The further board may also be a printed circuit board comprising: at least one sensor device for contactless measurement of a current intensity of a current flowing through an electrical line in a passage.

The fact that a plurality of sensor devices are used enables relatively precise measurement of the current intensity even when the electrical line does not rest perfectly at the point in the passage at which it should rest. The signals measured by two different sensor devices associated with the same passage can be compared with one another in order to make a relatively precise statement on the actual current intensity.

This applies to an increased extent when each printed circuit board comprises two sensors alike and said sensors are arranged symmetrically with respect to one another when the boards are coupled.

In one embodiment, a sensor device is one which comprises a sensor utilizing a magnetoresistive effect. This may be the anisotropic magnetoresistive effect, the giant magnetoresistive effect, the tunnel magnetoresistive effect or other effects. A sensor utilizing such a magnetoresistive effect includes a line section including a magnetoresistive material and changes its resistance under the effect of a magnetic field, and the sensor then need only be able to detect this change. The magnetic field in this case originates from the current flowing through the electrical line in the passage.

As an alternative or in addition, at least one sensor device may include a Hall sensor (a sensor in which a Hall voltage is produced owing to the effect of a magnetic field) with this Hall voltage being measured and being a measure of the coupled-in magnetic field.

Even retrofitting for measurement of further variables is easier. At least one printed circuit board can comprise a device with an electrode for measuring a voltage zero crossing capacitively. In this way, the phase angle can be measured relatively precisely in the case of a three-phase current. This capacitive measurement is naturally also contactless.

In this case, a printed circuit board is used at least in the case of the pair of boards because, in addition to the actual sensor devices, the cabling (conductive connections) can also be provided on such a printed circuit board. The printed circuit board can comprise a device for reading and evaluating the measured values from the sensor devices, but the printed circuit board preferably comprises only one interface for reading the measured values, which is coupled via conductive connections to the at least one sensor device (and, when using the electrodes for the capacitive voltage determination, also coupled to this device). Therefore, the actual measuring device can be attached to the combination of the two boards coupled to one another at a point where it causes little destruction. The two boards are relatively light, when using the interface on one of the printed circuit boards, and can therefore be fitted to the electrical lines without any considerable complexity.

In order to facilitate fitting to electrical lines with a given, desired or predetermined diameter, the passages can be designed straightaway appropriately for the electrical lines. Mutually complementary inserts may be used on both boards, to be relatively precise in the region of the passage provided, in order that these inserts can surround the electrical lines and provide a fixed hold for the two boards coupled to one another and favorable centering of the surrounded line.

In the context of the provision of the pair according to at least one embodiment, a printed circuit board with at least one magnetoresistive sensor and/or at least one Hall sensor may be used.

In a method for measuring the current intensity of a current flowing through an electrical line according to at least one embodiment, provision is made for a pair of two boards to be fitted (on the electrical line or on a device which itself holds the electrical line), with this pair being a pair of boards as discussed herein. The attachment may occur in such a way that a passage is provided between the two boards, through which passage the electrical line passes. As mentioned above, such an attachment is readily possible because the two boards each need to be held simply only on the electrical line. The at least one sensor device is used for measuring the current intensity, for which purpose, when using the interface on one printed circuit board, possibly a measuring device which reads and evaluates the measured values needs to be attached.

In a method for retrofitting a switchgear cabinet with a plurality of electrical lines (with which in each case one securing device is associated) according to at least one embodiment, the method for measuring the current intensity is implemented, wherein a pair of two boards is used which provides an aperture for each of the electrical lines when coupled to one another and has at least one sensor device for each of these passages. In this way, the current through all or substantially all of the electrical lines can be detected. The values for the current intensity are therefore available relatively quickly without any further measures.

### BRIEF DESCRIPTION OF THE DRAWINGS

Example embodiments will be described in more detail below with reference to the drawings, in which:

FIG. 1 shows an embodiment of a pair of printed circuit boards, illustrated in plan view,

FIG. 2 shows such a pair together with electrical lines shown in cross section,

FIG. 3 shows a pair of printed circuit boards of the type shown in FIG. 1 with six passages in perspective view together with three electrical lines,

FIG. 4 shows the use of a pair of printed circuit boards in a switchgear cabinet with ten electrical lines,

FIG. 5 shows an embodiment of a pair of printed circuit boards, which has been supplemented in comparison with the embodiment shown in FIG. 1, and

FIGS. 6 and 7 show, in plan view, how inserts can be inserted, with FIG. 6 showing the inserts in the non-inserted state and FIG. 7 showing the inserts in the inserted state.

### DETAILED DESCRIPTION

Various example embodiments will now be described more fully with reference to the accompanying drawings in which only some example embodiments are shown. Specific structural and functional details disclosed herein are merely representative for purposes of describing example embodiments. The present invention, however, may be embodied in many alternate forms and should not be construed as limited to only the example embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the present invention to the particular forms disclosed. On the contrary, example embodiments are to cover all modifications, equivalents, and alternatives falling within the scope of the invention. Like numbers refer to like elements throughout the description of the figures.

Specific structural and functional details disclosed herein are merely representative for purposes of describing example embodiments of the present invention. This invention may, however, be embodied in many alternate forms and should not be construed as limited to only the embodiments set forth herein.

It will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments of the invention. As used herein, the singular forms “a,” “an,” and “the,” are intended to include the plural forms as well, unless the context clearly indicates otherwise. As used herein, the terms “and/or” and “at least one of” include any and all combinations of one or more of the associated listed items. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, term such as “below” can encompass both an orientation of above and below. The device may be otherwise oriented (rotated 90 degrees or at other orientations) and the spatially relative descriptors used herein are interpreted accordingly.

Although the terms first, second, etc. may be used herein to describe various elements, components, regions, layers and/or sections, it should be understood that these elements, components, regions, layers and/or sections should not be limited by these terms. These terms are used only to distinguish one element, component, region, layer, or section from another region, layer, or section. Thus, a first element, component, region, layer, or section discussed below could be termed a second element, component, region, layer, or section without departing from the teachings of the present invention.

As a basic module for a device for measuring the current intensity of a current flowing through electrical lines (e.g., in a switchgear cabinet), two printed circuit boards 10 and 12 are provided, which each have a plurality of recesses 14, 16, which are in this case precisely semicircular, but could also be slightly less than semicircular. The recesses 14 and 16 supplement one another in each case to form a passage 18, which in this case is circular owing to the semicircular form of the individual recesses 14 and 16.

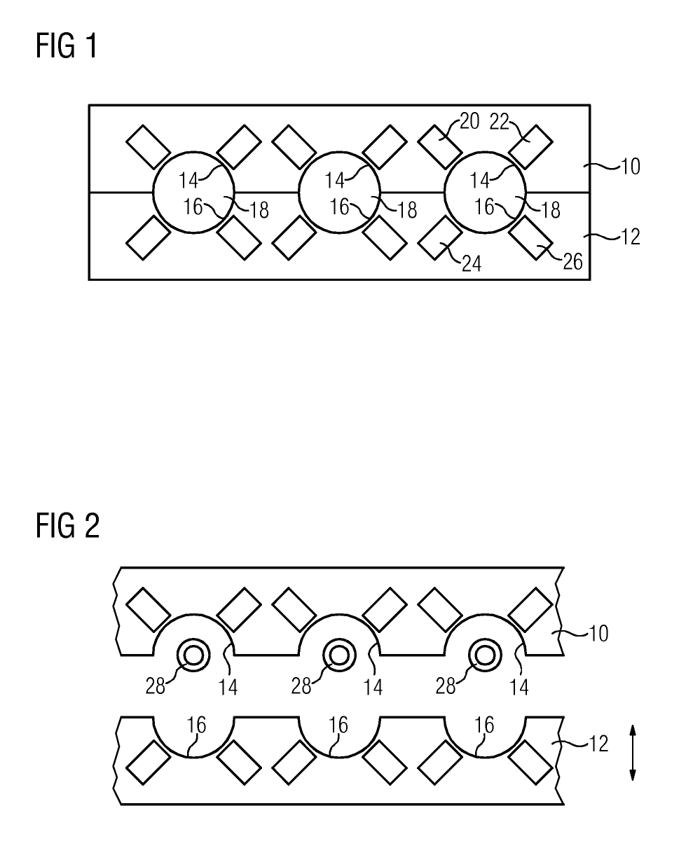

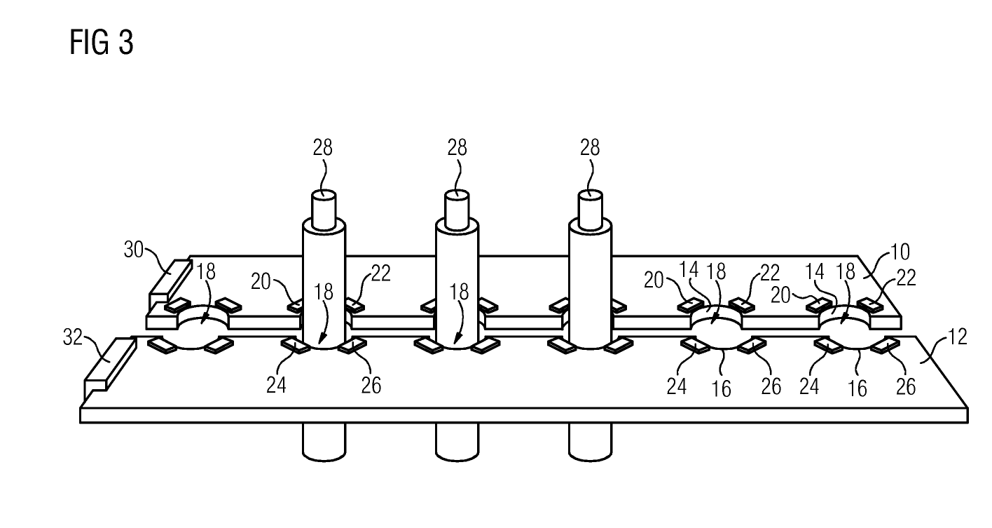

FIG. 1 shows two printed circuit board halves 10 and 12, which provide precisely three passages; FIG. 2 shows merely one detail of relatively large printed circuit boards which is correspondingly large; and FIG. 3 shows two printed circuit boards 10 and 12 with recesses for six passages. For reasons of clarity, the printed circuit boards 10 and 12 and the recesses 14 and 16 have been provided with the same reference symbols in all pairs of printed circuit boards.

Each printed circuit board 10, 12 has two sensors 20, 22 (for printed circuit board 10) and 24, 26 (for printed circuit board 12) for each recess 14, 16 or for each passage 18. The sensors are arranged rotationally symmetrically with the symmetry number four with respect to one another when the printed circuit boards 10 and 12 are coupled to one another so as form the passage 18. In each case, two mutually complementary pairs of sensors 20, 26 on one side, and 22, 24, on the other side make a comparison possible in a measurement. The sensors 20, 22, 24, 26 are, in this case, designed for contactless magnetic field measurement and are therefore capable of measuring the current intensity of a current flowing through an electrical line 28 in the passage 18. Such sensors may be magnetoresistive sensors or Hall sensors. The printed circuit boards 10 and 12 bear cabling (conductive connections) not shown in the figures for the sensors 20, 22, 24, 26, which lead to two interfaces 30 (printed circuit board 10) and 32 (printed circuit board 12). The measured values of the sensors 20, 22, 24, 26 can be read via these interfaces by virtue of a measuring device 34 being coupled.

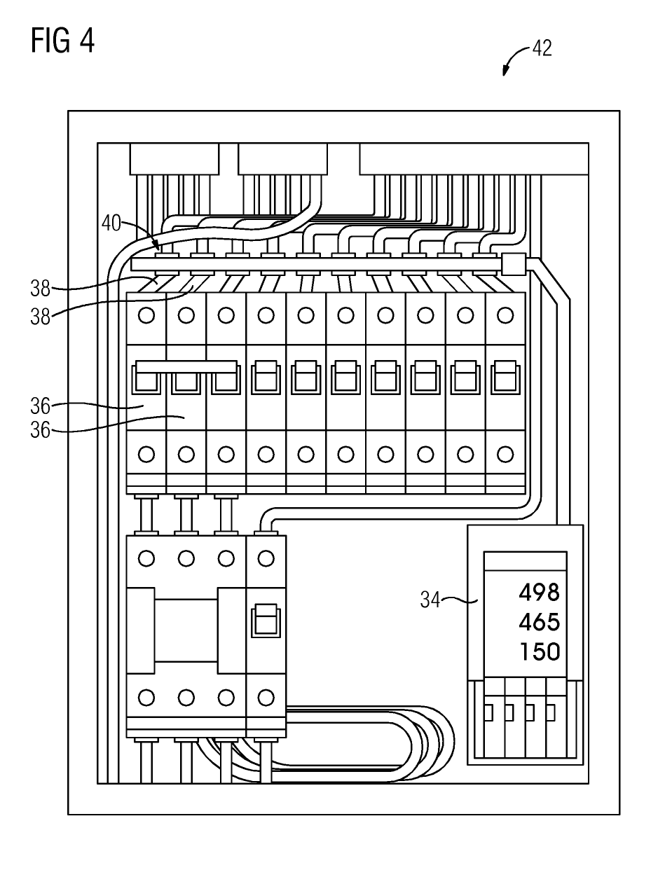

FIG. 4 shows the purpose of the two printed circuit boards 10 and 12. In a switchgear cabinet 42, there is a plurality of fuse units 36, to which, in each case, one electrical line 38 leads. One intention now is to measure the current intensity of the current flowing through each electrical line individually. Therefore, one of the printed circuit boards 10 or 12 is pushed below or behind the electrical lines 38, and the other of the printed circuit boards 10, 12 is positioned on the electrical line 38 from the front or above, in a similar way to that shown in FIG. 3. Either the printed circuit boards 10, 12 for their part have coupling devices (e.g., latching tabs and latching depressions) such that they can be connected to one another themselves, or suitable connection mechanism or device 40 are used for fastening the two printed circuit boards 10, 12 to one another.

In the case of the switchgear cabinet 42 shown in FIG. 4, there is the possibility for ten electrical lines 38 for the current intensity of the current flowing through each of said electrical lines to be measured, with the interfaces 30, 32 of the two printed circuit boards 10, 12 being coupled to the device 34 that, with suitable programming, is capable of specifying the individual current intensity values, storing these values and outputting said values to further devices etc.

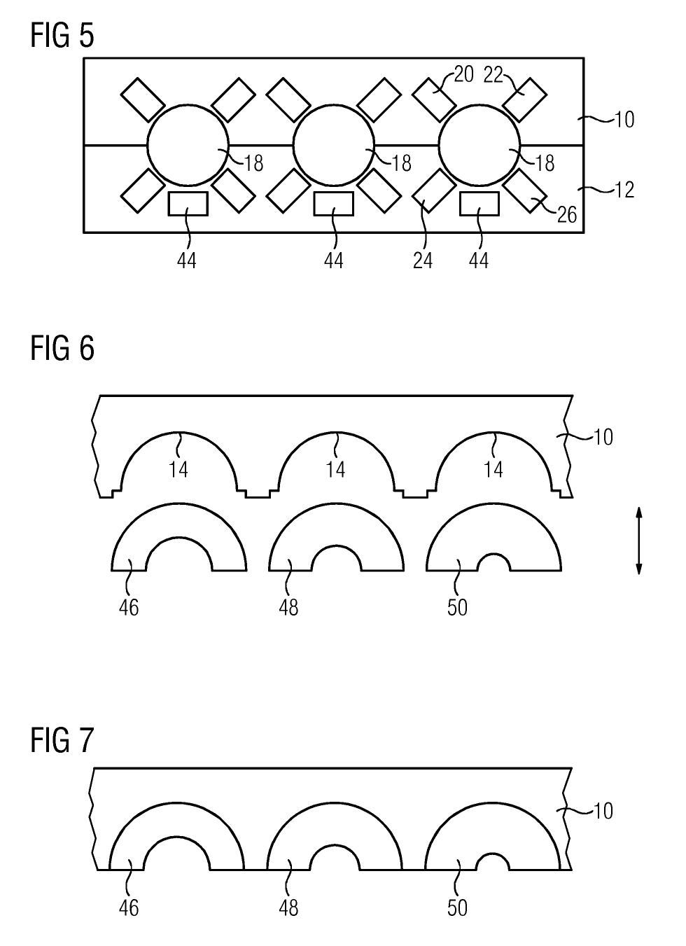

As a development of the embodiment shown in FIG. 1, in addition to the sensors 20, 22, 24, 26, a further electrode 44 can also be provided in at least one of the printed circuit boards 10, 12 (in this case in the printed circuit board 12) for each passage 18, said electrode providing the possibility of a capacitive voltage measurement. Although it may not possible to precisely determine the amplitude of the voltage, the zero crossings of the voltage and therefore the determination of the phase angle between the current and the voltage (the so-called cosine φ) can be determined. Thus, the previously described current measurement can be extended to power measurement. Furthermore, it is possible to determine, by detecting the voltage, whether individual ones of the fuse units 36 have been triggered or switched off. In order that the electrical lines 28 have a more secure hold in the passages 18, inserts can be provided which can be inserted into the recesses 14 (or else 18, not shown). Such inserts are shown in FIG. 6, to be precise one insert 46 for a large electrical line diameter, one insert 48 for a medium electrical line diameter and one insert 50 for a relatively small electrical line diameter. The outer diameters of the inserts are in this case designed so as to match the recesses 14 (or 16) such that the inserts can be inserted, corresponding to their name, into the recesses 14, as is illustrated in FIG. 7.

In one embodiment, the inserts include plastic (e.g., of foam), and provide the possibility of relatively precise positioning of the printed circuit boards 10 and 12 with respect to the electrical lines 28 (or other electrical lines with a different diameter), with the result that the abovementioned compensation between the sensors 20, 26 or 22, 24 is only necessary to a restricted degree.

The compensation between the sensors 20, 26 and 22, 24 in this case includes the fact that both sensors 22, 24, with the same design, also need to output the same signal, assuming there is a central electrical line 28. If this is not the case, it is assumed that the electrical line is not central, to be precise is shifted along an axis connecting each of the two sensors 20, 26 or 22, 24. This can be taken into consideration in the evaluation of the measurement signals.

The use of four sensors 20, 22, 24, 26 at the same time for each passage 18 and at the same time associated inserts 46, 48, 50 therefore provides a possibility of a more precise measurement of the current intensity.

Example embodiments being thus described, it will be obvious that the same may be varied in many ways. Such variations are not to be regarded as a departure from the spirit and scope of the present invention, and all such modifications as would be obvious to one skilled in the art are intended to be included within the scope of the following claims.

### LIST OF REFERENCE SYMBOLS

10 Printed circuit board
12 Printed circuit board
14 Recesses
16 Recesses
18 Passage
20 Sensors
22 Sensors
24 Sensors
26 Sensors
28 Electrical lines
30 Interface
32 Interface
34 Measuring device
36 Fuse units
38 Electrical lines
40 Connecting means
42 Switchgear cabinet
44 Electrode
46 Insert
48 Insert
50 Insert

What is claimed is:

1. A pair comprising:
a printed circuit board; and
a further board coupled to the printed circuit board such that at least one passage for an electrical line is provided by the coupling of the printed circuit board and the further board to one another, the printed circuit board including,
at least one sensor device for contactless measurement of a current intensity of a current flowing through the electrical line in the at least one passage.

2. The pair as claimed in claim 1, wherein the further board is a printed circuit board, and the further board includes,
at least one sensor device for contactless measurement of the current intensity of the current flowing through the electrical line in the at least one passage.

3. The pair as claimed in claim 2, wherein each printed circuit board comprises:
at least two sensors arranged symmetrically with respect to one another when the printed circuit boards are coupled to one another.

4. The pair as claimed in claim 1, wherein the sensor device includes a sensor configured to utilize a magnetoresistive effect.

5. The pair as claimed in claim 1, wherein the sensor device includes a Hall sensor.

6. The pair as claimed in claim 1, wherein the printed circuit board comprises:
a device having an electrode to capacitively measure a voltage zero crossing.

7. The pair as claimed in claim 1, wherein the printed circuit board comprises:
an interface to read values of the measurement, the interface being coupled to the at least one sensor device via conductive connections.

8. The pair as claimed in claim 1, further comprising:
a plurality of mutually complementary inserts on each of the printed circuit board and the further board in the region of the passage, the plurality of mutually complementary inserts being configured to embrace the electrical line.

9. The pair as claimed in claim 1, wherein the printed circuit board comprises:
at least one of a magnetoresistive sensor and a Hall sensor.

10. A method for measuring a current intensity of a current flowing through an electrical line, the method comprising:
mounting a printed circuit board and a further board together to provide at least one passage for the electrical line, the printed circuit board including at least one sensor device for contactless measurement of the current intensity of the current flowing through the electrical line in the at least one passage; and
using the at least one sensor device to measure the current intensity.

11. A method for retrofitting a switchgear cabinet with a plurality of electrical lines, the method comprising:
mounting a printed circuit board and a further board together to provide a passage for each of the plurality of electrical lines, the printed circuit board including a plurality of sensor devices for contactless measurement of a current intensity of a current flowing through each of the plurality of electrical lines; and
using the plurality of sensor devices to measure the current intensity.

12. The pair as claimed in claim 3, wherein the at least two sensors are arranged rotationally symmetrically with respect to one another.

13. The pair as claimed in claim 2, wherein the sensor device comprises:
a sensor configured to utilize a magnetoresistive effect.

14. The pair as claimed in claim 2, wherein each of the sensor devices includes a Hall sensor.

15. The pair as claimed in claim 6, wherein the printed circuit board comprises:
an interface to read the measured values, the interface being coupled via conductive connections to the at least one sensor device and to the device.
